(19) United States
(12) Patent Application Publication
(10) Pub. No.: US 2026/0009865 A1
(43) Pub. Date: Jan. 8, 2026

(54) Online Health Monitoring Systems for a Direct Current (DC)-Link Capacitor and Related Methods

(71) Applicant: Eaton Intelligent Power Limited, Dublin 4 (IE)

(72) Inventors: Priyabrata Shaw, Balasore (IN); Nikhil Kumar Sharma, Bilaspur (IN); Prasad Venikar, Pune (IN); Thomas Farr, Candler, NC (US)

(21) Appl. No.: 19/254,528

(22) Filed: Jun. 30, 2025

Related U.S. Application Data
(60) Provisional application No. 63/666,887, filed on Jul. 2, 2024.

(51) Int. Cl. G01R 31/64; G01R 27/26; H02M 1/32

(52) U.S. Cl. CPC G01R 31/64; G01R 27/2605; H02M 1/32

(57) ABSTRACT

Some embodiments of the present inventive concept provide a health monitoring system for monitoring the health of DC-link capacitors. The system includes a controller that hosts a health monitoring algorithm that computes a capacitance of the DC-link capacitor and estimates the health of the capacitor. The controller measures a DC-link voltage; filters high-frequency noise from voltage; obtains a peak value a minimum value of a DC-link voltage from the filtered DC-link voltage; calculates a drive output power from the measured DC-link voltage; calculates a charging time duration for the DC-link capacitor; calculates a DC-link capacitance using the peak and minimum voltage magnitudes, calculated charging time duration, calculated drive output power, and frequency; compares the calculated DC-link capacitance with a measured baseline DC-link capacitance to determine a reduction in capacitance; and determines the health of the DC-link capacitor based on the calculated reduction in capacitance.

### CROSS-REFERENCE TO RELATED APPLICATION

This application claims the benefit of and priority to U.S. Provisional Application No. 63/666,887, filed on Jul. 2, 2024, the content of which is hereby incorporated herein by reference in its entirety.

### FIELD

The present inventive concept relates generally to electronic circuits and, more particularly, to monitoring performance of Direct Current (DC)-link capacitors used in two-stage rectifier inverter systems such as variable frequency drives (VFDs).

### BACKGROUND

Power converters are vital to the power industry for their applications in, for example, uninterrupted power supplies (UPSs), electric heating, and motor drives. Such power converters are used in variable frequency drives (VFDs) to control the motor at a desired speed. Power devices, inductors, capacitors, and the like are integral parts of the VFD. A Direct Current (DC)-link capacitor works as DC power storage and filters out variations in voltage, acting as an intermediate stage for two converters: rectifier and inverter. Different types of capacitors such as ceramic, film, and electrolytic type capacitors can be used as DC link capacitors, electrolytic being the most commonly used.

Despite their importance, DC-link capacitors may be fragile and prone to degradation. The failure of a DC link capacitor can lead to reduced efficiency and system downtime.

Current solutions to this problem are limited by several key factors. Some methods are offline and generally require disconnecting the drive. Other methods generally require additional hardware or injection circuitry or modification of existing hardware. Additionally, some solutions may only be applicable to specific types of capacitors. Thus, improvements are desired.

### SUMMARY

Some embodiments of the present inventive concept provide a health monitoring system for monitoring the health of DC-link capacitors. The system includes a controller that hosts a health monitoring algorithm that computes a capacitance of the DC-link capacitor and estimates the health of the capacitor. The controller measures a DC-link voltage, wherein the DC-link voltage is a direct current voltage between a rectifier and an inverter; filters high-frequency noise from the measured DC-link voltage; obtains a peak value of the DC-link voltage and a minimum value of a DC-link voltage from the filtered DC-link voltage; calculates a drive output power from the measured DC-link voltage and current signals; calculates a charging time duration for the DC-link capacitor using a magnitude of the obtained peak value of the DC-link voltage and a magnitude of the minimum value of the DC-link voltage; calculates a DC-link capacitance using the peak and minimum voltage magnitudes, calculated charging time duration, calculated drive output power, and frequency; compares the calculated DC-link capacitance with a baseline DC-link capacitance to determine a reduction in capacitance; and determines the health of the DC-link capacitor based on the calculated reduction in capacitance from the baseline value computed at initial commissioning stage.

In further embodiments, when a percentage reduction in capacitance exceeds a threshold value, the controller may issue a warning signal indicating that the DC-link capacitor needs to be replaced.

In still further embodiments, when a percentage reduction in capacitance does not exceed a threshold value, the controller may repeat the method until the threshold value is exceeded.

In some embodiments, the system may further include a low-pass filter and wherein the controller causes the low-pass filter to filter high frequency noise.

In further embodiments, the high frequency noise may be noise greater than 1 kHz.

In still further embodiments, the controller may calculate charging time duration (a) using the following equation: α=cos−1(Vdc2/Vdc1), wherein Vdc1 is the peak value and Vdc2 is the minimum value of DC link voltage.

In some embodiments, the controller may calculate the DC-link capacitance for a single-phase system using the following equation: Cdc=((π−α)/π) ((P0)/(fs(Vdc1+Vdc2) (Vdc1−Vdc2))), wherein Cdc is the DC-link capacitance; a is the charging time duration; Po is the load power; Vdc1 is the peak value and Vdc2 is the minimum value.

In further embodiments, the controller may further repeatedly calculate the DC-link capacitance using the peak and minimum voltage magnitudes, calculated charging time duration, calculated drive output power, and frequency and average the calculated DC-link capacitances.

In still further embodiments, the controller may compare the calculated DC-link capacitance with the measured DC-link capacitance to determine a reduction in capacitance using a voltage profile during discharging.

In some embodiments, the health monitoring system may monitor the health of the capacitor during running conditions.

In further embodiments, the system may further include a grid; a VFD coupled to the grid; the controller; a display; and an induction motor (IM), wherein the grid-connected VFD drives the induction motor in which the power converters are connected through an intermediate DC-link capacitor.

Related methods are also provided.

### BRIEF DESCRIPTION OF THE FIGURES

Throughout the drawings, reference numbers can be re-used to indicate correspondence between referenced elements. The drawings are provided to illustrate embodiments of the present disclosure and do not to limit the scope thereof.

FIG. 1 is a diagram illustrating a system architecture for the integration of an online capacitor health monitoring solution in accordance with some embodiments of the present inventive concept.

FIG. 2 is a schematic diagram that illustrates a combination of online DC-link voltage-based and discharge voltage profile-based approaches for use in the health monitoring methods in according with embodiments of the present inventive concept.

FIG. 3 is a schematic diagram illustrating a DC-Link voltage waveform for a single-phase variable frequency drive in accordance with some embodiments of the present inventive concept.

FIG. 4 is a flowchart illustrating operations of a health monitoring system in accordance with some embodiments of the present inventive concept.

FIG. 5 is a diagram illustrating the DC-Link voltage discharge profile in accordance with some embodiments of the present inventive concept.

FIG. 6 is a picture illustrating a set for testing the method of health monitoring in accordance with some embodiments of the present inventive concept.

FIG. 7 is schematic diagram of a DC-Link Capacitor in accordance with some embodiments of the present inventive concept.

FIGS. 8A and 8B are Tables 1 and 2, respectively, illustrating experimental measurements in accordance with some embodiments of the present inventive concept.

FIGS. 9A through 9E are waveforms illustrating an experimental DC-Link Capacitor in accordance with some embodiments of the present inventive concept.

FIGS. 10A through 10E are waveforms illustrating an experimental DC-Link Capacitor in accordance with some embodiments of the present inventive concept.

FIG. 11 is a graph illustrating DC-link voltage discharge profile in accordance with some embodiments of the present inventive concept.

### DETAILED DESCRIPTION OF EMBODIMENTS

The inventive concept now will be described more fully hereinafter with reference to the accompanying drawings, in which illustrative embodiments of the inventive concept are shown. This inventive concept may, however, be embodied in many different forms and should not be construed as limited to the embodiments set forth herein; rather, these embodiments are provided so that this disclosure will be thorough and complete, and will fully convey the scope of the inventive concept to those skilled in the art. Like numbers refer to like elements throughout. As used herein, the term “and/or” includes any and all combinations of one or more of the associated listed items. Similarly, as used herein, the word “or” is intended to cover inclusive and exclusive OR conditions. In other words, A or B or C includes any or all of the following alternative combinations as appropriate for a particular usage: A alone; B alone; C alone; A and B only; A and C only; B and C only; and A and B and C.

The terminology used herein is for the purpose of describing particular embodiments only and is not intended to be limiting of the inventive concept. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and this specification and will not be interpreted in an idealized or overly formal sense unless expressly so defined herein.

Reference will now be made in detail in various and alternative example embodiments and to the accompanying figures. Each example embodiment is provided by way of explanation, and not as a limitation. It will be apparent to those skilled in the art that modifications and variations can be made without departing from the scope or spirit of the disclosure and claims. For instance, features illustrated or described as part of one embodiment may be used in connection with another embodiment to yield a still further embodiment. Thus, it is intended that the present disclosure includes modifications and variations that come within the scope of the appended claims and their Equivalents.

As discussed in the background, power converters are important elements and have many applications. Power converters are used extensively in variable frequency drives (VFDs) to control the motor at a desired speed. The power devices, inductors, and capacitors are vital parts of the VFDs. The direct current (DC)-link capacitor acts as an intermediate stage for two converters: rectifier and inverter. This capacitor works as DC power storage and filters variations in DC voltage before feeding it to the inverter. Further, different types of capacitors such as ceramic, film, and electrolytic type capacitors are used as DC-link capacitors. The electrolytic capacitor is the most utilized capacitor due to its small package size, large power density, and lower cost. These capacitors are the vital components in the drive but are also the most failure-prone. Some conventional methods for health monitoring provide solutions that are offline and generally require disconnection of the drive. Further methods require additional hardware or injection circuitry for capacitance degradation estimation. Finally, some solutions are only applicable to specific types of capacitors.

Accordingly, some embodiments of the present inventive concept provide a solution for the health monitoring of capacitors and address the shortcomings of the current methods discussed above. Systems in accordance with embodiments discussed herein can detect early signs of degradation and, thereby, improve the reliability of electronic systems as will be discussed further below with respect to the Figures.

In particular, some embodiments of the present inventive concept provide a solution for the health monitoring of the capacitors that discusses mathematical expressions derived for the computation of the near exact capacitance based on supply frequency, DC-link voltage, and drive power. As will be discussed, the DC-link voltage signal is acquired, and the capacitance is computed based on the current operating condition. The difference between the estimated capacitance and the original capacitance is used to estimate the capacitor degradation, which may then act as an index for monitoring the health of the DC-link capacitor. Furthermore, in some embodiments an indication of failure of the capacitor (end of life) is provided if the capacitance value falls below a threshold value.

As used herein. “health” of a capacitor refers to a capacitors ability to store and release electrical charge as intended, without significant degradation in performance. A healthy capacitor maintains its rated capacitance, has a low equivalent series resistance (ESR), and exhibits no physical damage. Degradation can manifest as reduced capacitance, increased ESR, leakage, or physical defects like bulging or swelling.

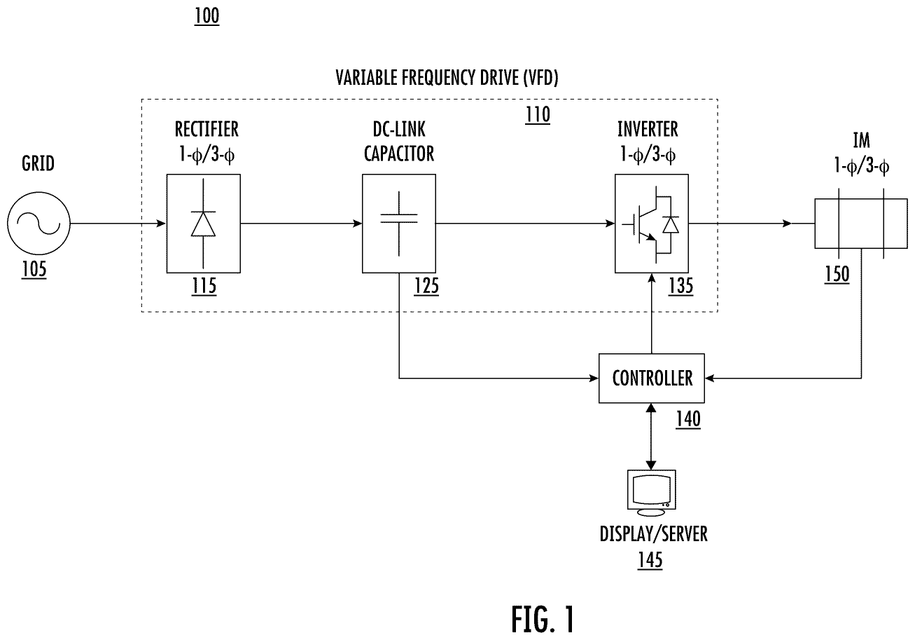

Referring first to FIG. 1, a diagram illustrating the system and architecture 100 of the online capacitor health monitoring system will be discussed. Embodiments of the present inventive concept rely on use of a DC-link voltage signal and measurement of drive power to provide a health estimation of a capacitor. As illustrated in FIG. 1, the system includes a grid 105 coupled to a VFD 110, a controller 140, a display 145 and an induction motor (IM) 150. The grid-connected VFD drives the induction motor 150 in which the power converters (rectifier 115 and inverter 135) are connected through an intermediate DC-link capacitor 125. The controller 140 hosts the health monitoring algorithm in some embodiments. However, embodiments of the present inventive concept are not limited thereto. The controller 140 acquires the voltage from the DC-link capacitor 125 and computes the power based on the voltage and current signals from the induction motor terminals 150. The health monitoring system in accordance with embodiments discussed herein utilizes the magnitude of DC-link voltage and motor power to compute the capacitance and estimate the health of the capacitor. The controller can also be connected to the display/server 145, which can show the capacitor's health information, and certain inputs can also be communicated to the controller 140 from the server 145.

Although embodiments of the present inventive concept are discussed with respect to power modules and inverters, embodiments are not limited thereto. Embodiments discussed herein can be used with any solid state device, for example, solid state transformers, without departing from the scope of the present inventive concept.

As used herein, a “grid” (also known as a power grid or an electric grid) is a network of infrastructure that generates, transmits, and distributes electricity to consumers. It may connect power plants to substations and ultimately to homes and businesses, ensuring a reliable supply of power.

As used herein, “baseline capacitance refers to the initial capacitance value when the system in which the capacitor is used is deployed. Furthermore, although embodiments are discussed herein as a controller based edge application, embodiments of the present inventive concept are not limited thereto. For example, if the drive communicates required data to on premise or cloud application, then the necessary calculations can be performed at that location and is not limited to edge application.

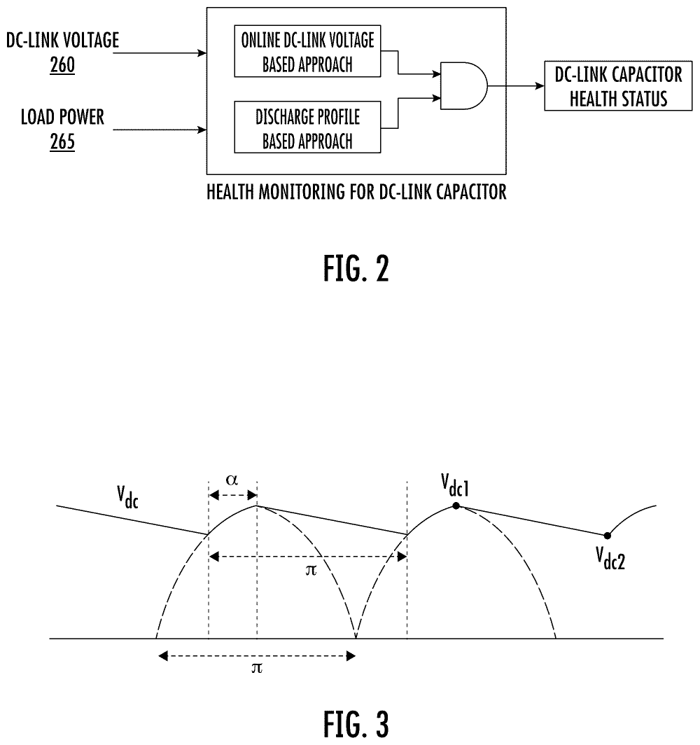

The capacitor health monitoring system in accordance with embodiments of the present inventive concept relies on a combination of online DC-link voltage-based and discharge voltage profile-based approaches as illustrated, for example, in FIG. 2. As illustrated, the inputs to the capacitor health monitoring system include a DC-link voltage 260 and load power 265. These two elements estimate the change in capacitance values and, if both the estimated values cross a predetermined degradation threshold, a capacitor replacement warning may be issued be issued. The predetermined degradation threshold may be, for example, 10% in some embodiments. The warning may be delivered in many formats without departing from the scope of the present inventive concept. The continuous health of the DC-Link capacitors may be displayed based on the average of the estimated values from the two approaches. However, embodiments are not limited thereto.

In some embodiments, the capacitance may be estimated using an online DC-link voltage. In particular, the front-end converter of the VFD 110 (FIG. 1) converts the alternating current (AC) into DC and is known as a rectifier 115, which can be in one of, for example, diode, thyristor, and insulated gate bipolar transistor (IGBT)-based configurations. The output port of the rectifier 115 contains the DC-link capacitor 125 that delivers smooth DC voltage to the inverter module 135 of the VFD 110. This DC-link voltage indicates the behavior of the capacitor over time, which can be identified by measuring the peak and minimum values of the voltage profile.

For a normal single-phase rectifier, the voltage profile across a DC-link voltage is illustrated in FIG. 3, where V_{dc1} represents the peak value and V_{dc2} represents the minimum value of the DC-link voltage. This voltage profile of the DC-link voltage depends on the charging/discharging duration and the capacitance value. The charging time duration (a) of the DC-link capacitor can be computed based on the values of V_{dc1} and V_{dc2}. During discharging time (π−α), the capacitor discharges to the load through the inverter 135. Now, by energy balance, the capacitance value is obtained in terms of DC-link voltage (V_{dc}) and load power (P₀) and is given by Eqn. (1) below. Where the charging time duration of the DC-link capacitor can be obtained through Eqn. (2) below. The same analysis is extended to the three-phase rectifier and the capacitance expression is obtained as Eqn. (3) below. These expressions (Eqn. (1) and (3)) can be utilized to estimate the capacitance value of the DC-link capacitor of single-phase and three-phase VFD systems during normal operations. Thereafter, by comparing the estimated and original capacitance values, the health of the capacitor can be monitored.

For single phase:

$${C}_{dc} = ( ( π - α ) / π ) ( ( {P}_{0} ) / ( {f}_{s} ( {V}_{dc 1} + {V}_{dc 2} ) ( {V}_{dc 1} - {V}_{dc 2} ) ) ) \qquad Eqn . ( 1 )$$

$$α = {cos}^{- 1} ( {V}_{dc 2} / {V}_{dc 1} ) \qquad Eqn . ( 2 )$$

For three-phase:

$${C}_{dc} = ( ( π - 3 α ) / π ) ( ( {P}_{0} ) / ( 3 {f}_{s} ( {V}_{dc 1} + {V}_{dc 2} ) ( {V}_{dc 1} - {V}_{dc 2} ) ) ) \qquad Eqn . ( 3 )$$

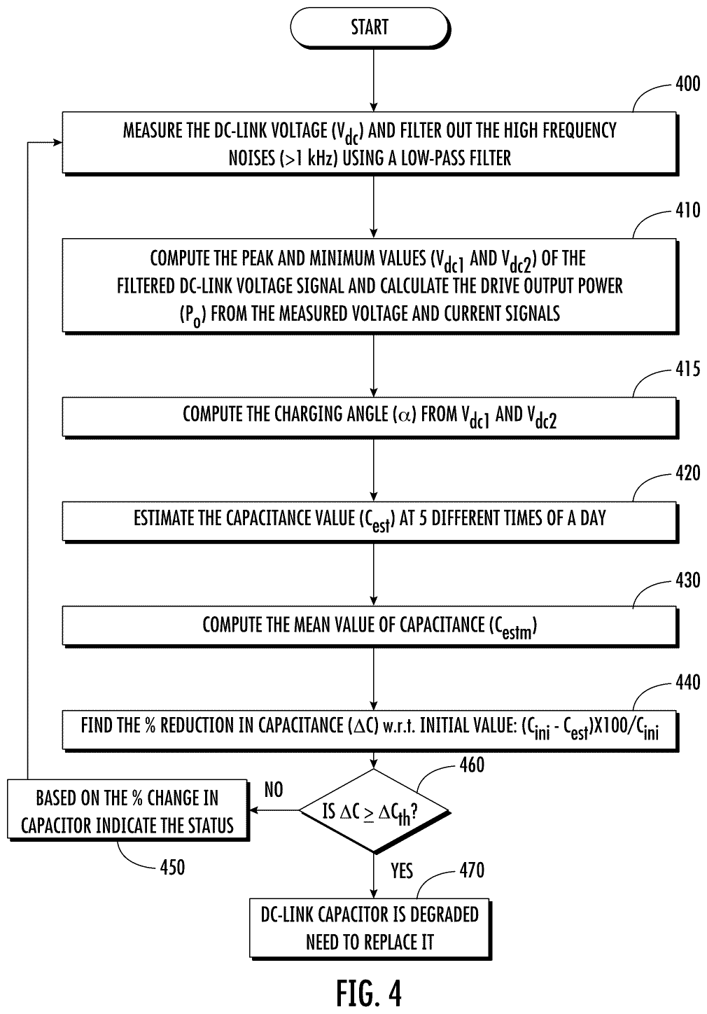

Operations of a health monitoring system for the DC-link capacitor in accordance with some embodiments are illustrated in the flowchart of FIG. 4. The DC-link voltage is measured and then the high-frequency noises (>1 kHz) are filtered out from the acquired DC-link voltage signal using a low-pass filter (block 400). The peak and minimum value of DC-link voltage are obtained from the filtered voltage signal and the drive output power is calculated from the measured voltage and current signals (block 410). The charging time duration is computed using the peak and minimum magnitude of the DC-link voltage as shown in Eqn. (2) (block 415). The capacitance is computed using the peak and minimum voltage magnitudes, charging time duration, drive output power, and frequency as shown in Eqns. (1) and (3) (block 420). The capacitance estimation may be performed several times a day and the average value for the day may be computed to reduce a number of measurement errors (block 430). Then the final estimated value is compared with the initial value of the capacitor, baseline state hereafter referred as “healthy state” and the reduction in capacitance is calculated (block 440). If the percentage reduction is more than a threshold value (e.g. 20% for electrolytic) (block 460), a warning will be issued in the display and the capacitor needs to be replaced (block 470). If the change in capacitance is less than the threshold value (block 460), the health monitoring algorithm will repeat itself and the current health of the capacitor can be displayed in terms of percentage degradation in capacitance (block 450). It will be understood that the steps provided in FIG. 4 are provided as examples only and embodiments of the present inventive concept are not limited thereto.

In some embodiments, capacitor degradation may be detected through a DC-link voltage discharging profile.

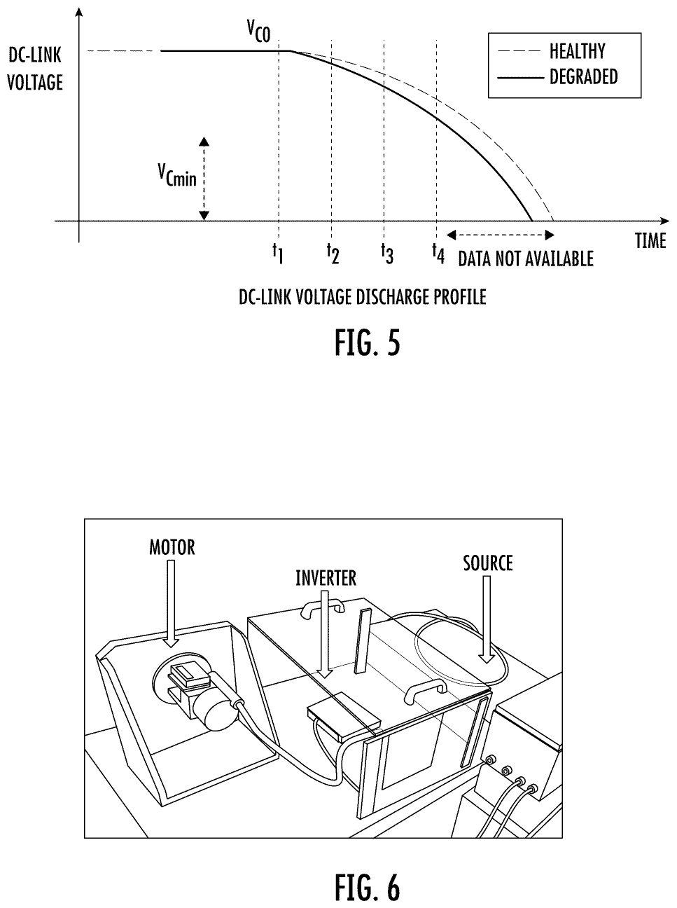

The DC-link capacitor degradation can also be detected using the voltage profile during discharging. Based on the discharging voltage data, the change in capacitance values of the DC-link capacitor is detected based on Eqn. (4) below.

$${V}_{dc} ( t ) = {V}_{C 0} {e}^{( - t / RC )} \qquad Eqn . ( 4 )$$

where V_{dc} is the DC-link voltage, V_{co} is the steady-state capacitor voltage, R is the combined internal resistance and ESR, C is the capacitance, and t is the discharge time. The discharge profile of DC-link capacitor is illustrated in FIG. 5 illustrates the voltage signal for a healthy and degraded capacitor. Due to the reduction in capacitance, the degraded capacitor discharges faster as compared to the healthy one. Thus, if the DC-link voltage is measured at regular time steps, the voltage will be lower for the degraded capacitor compared to the healthy one. The discharge profile of the capacitor can only be captured before the device turns off and thus after a certain number of samples (e.g. t₁ to t₄), the voltage data will not be available. By utilizing Eqn. (4) above, the following two expressions (Eqns. (5) and (6)) can be written for healthy (CH) and degraded (CD) capacitors, respectively. The relationship between the healthy and degraded capacitor, as shown in Eqn. (7), is derived from Eqns. (5) and (6), in terms of DC-link voltage signal of healthy and degraded capacitors. The DC-link voltage signals of healthy (V_{dcH}) and degraded (V_{dcD}) capacitors are measured, and the degraded capacitance value can be obtained in terms of initial healthy capacitance. If the change in capacitance is above the threshold (e.g. 20% for electrolytic type), a warning signal to replace the capacitor will be displayed. If the change is below the threshold, the health of the DC-link capacitor will be displayed.

$${V}_{dcH} ( t ) = ( {V}_{C o H} ) ( {e}^{- t / ( R {C}_{H} )} ) \qquad Eqn . ( 6 )$$

$${V}_{dcD} ( t ) = ( {V}_{C o D} ) ( {e}^{- t / ( R {C}_{D} )} ) \qquad Eqn . ( 7 )$$

$$( {C}_{D} / {C}_{H} ) = [ ln {V}_{dcH} ( t ) - ln {V}_{C 0 H} ] / [ ln {V}_{dcD} ( t ) - ln {V}_{C 0 D} ] \qquad Eqn . ( 8 )$$

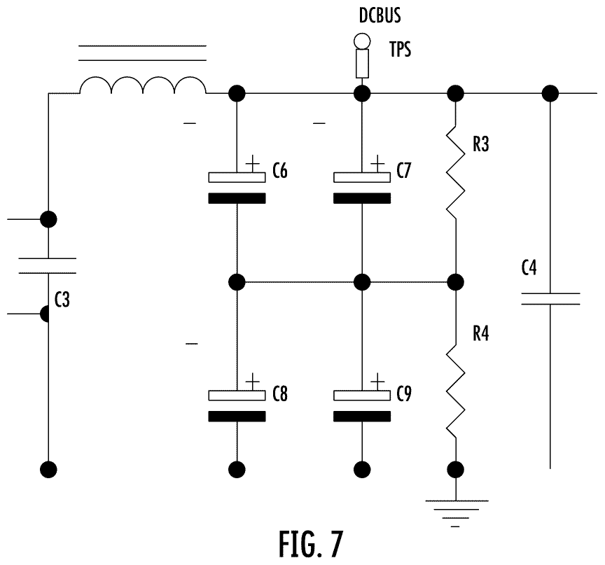

To validate the online health monitoring system discussed herein, experiments were performed. Details with respect to the experiments and the results thereof will be discussed below with respect to the Figures. The online capacitor monitoring approach verification was performed using a three-phase motor drive as shown in FIG. 6, motor, inverter and source. An example drive board may consist of a three-phase diode bridge rectifier and a three-phase IGBT inverter connected via the DC-link capacitors in accordance with embodiments discussed herein. In some embodiments, there may be four DC-link capacitors of value 470 μF each connected in series and parallel manner as shown in FIG. 7. However, it is understood that embodiments of the present inventive concept are not limited to this configuration and more or less DC-link capacitors may be included without departing from the scope of the present inventive concept. If all four capacitors in this embodiment are connected, the equivalent capacitance value ideally would be 470 μF. When capacitors C6 and C8 are disconnected, the effective capacitance should be half, i.e. 235 μF. The DC-link capacitance is estimated under these two conditions to verify the health monitoring technique in accordance with embodiments discussed herein at different values of capacitance to simulate aging conditions of capacitors.

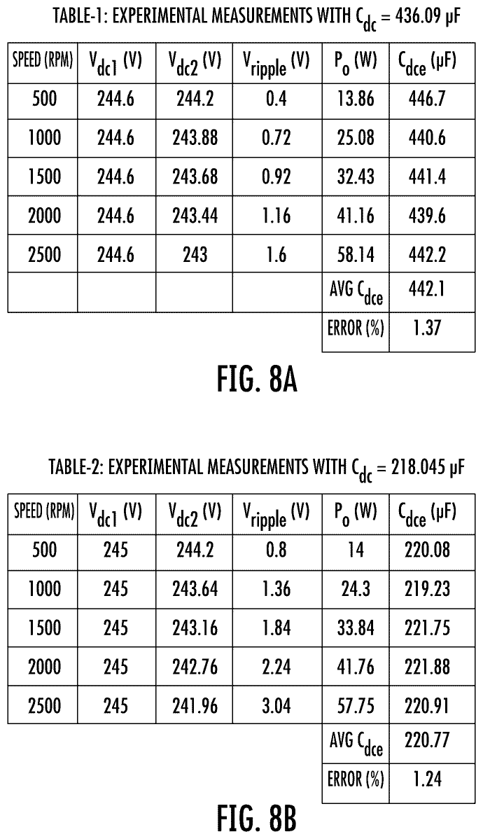

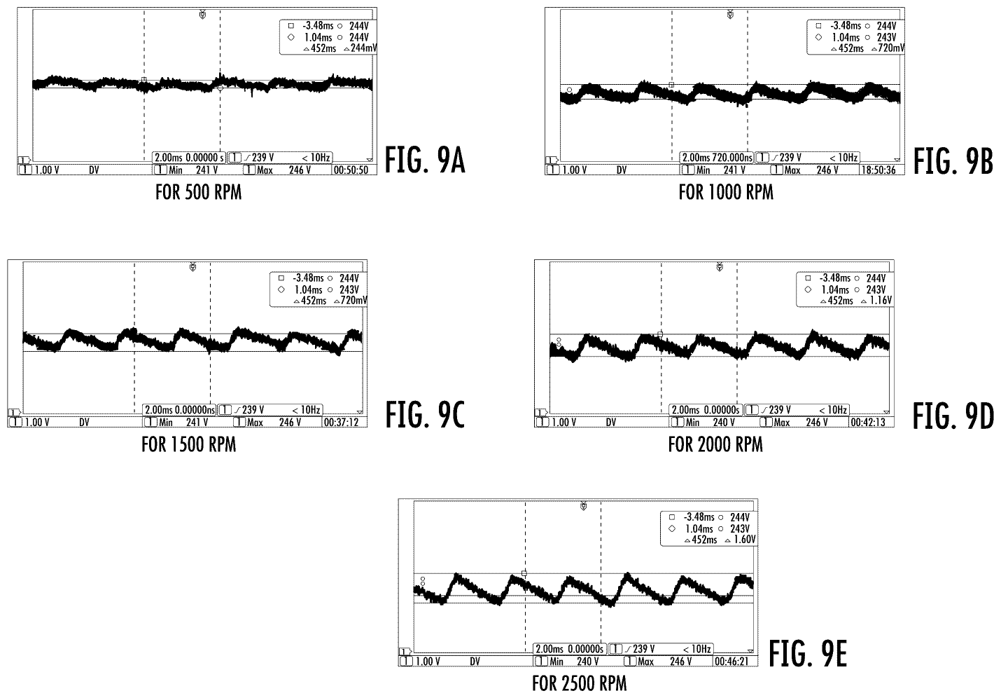

The measurements were captured for the two different values of the capacitances to verify the health monitoring approach that uses the capacitance estimation based on the DC-link voltage signal. For a fixed value of capacitance, the DC-link voltage signal is measured, and its peak and minimum values are computed for different load powers to estimate the capacitance using Eqn. (3) above. Table 1 of FIG. 8A illustrates the estimated capacitances for different values of load power at different motor speeds for the actual Cdc=436.09 μF. The respective measured waveforms of the DC-link voltage signal are illustrated in FIGS. 9A through 9E for different load power at different motor speeds, 500 rpm, 1000 rpm, 1500 rpm, 2000 rpm and 2500 rpm. The average value of the capacitance was computed for the estimated value as 442.1 pF with an error of 1.37%.

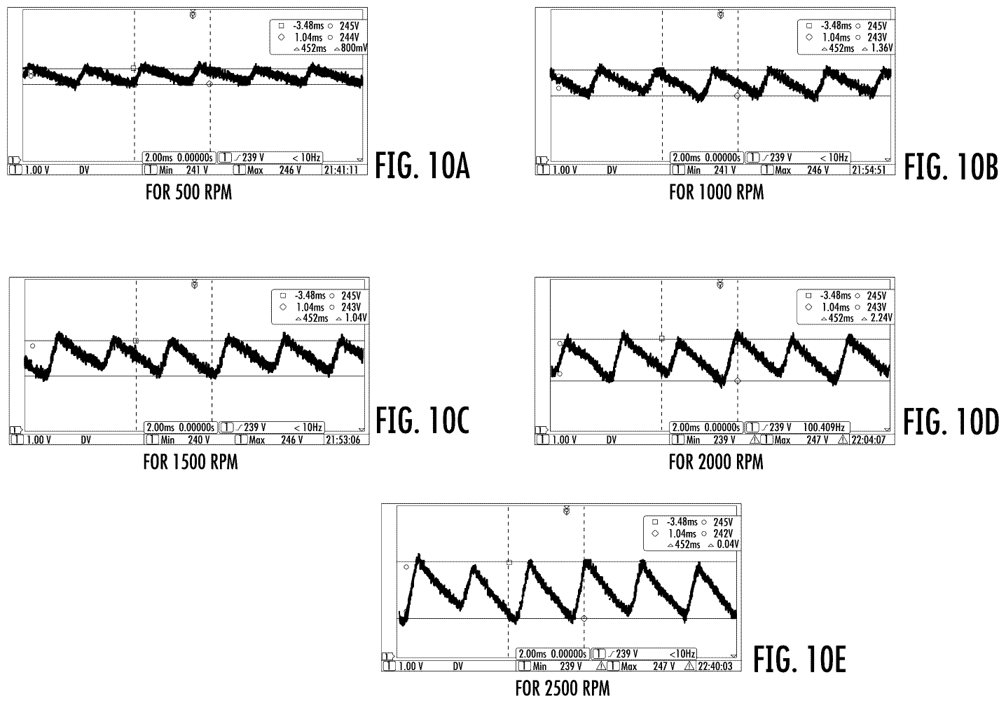

Similarly, Table 2 of FIG. 8B illustrates the estimated capacitances for different values of load power at different motor speeds for a 50% reduced capacitance value C_{dc}=218.045 μF), and the experimental waveforms of the DC-link voltage signal are presented in FIGS. 10A through 10E. In these embodiments, the proposed algorithm estimates the capacitance with 1.24% error as C_{dc}=220.77 μF. Thus, the estimated reduction in capacitance is 50.06% for a 50% actual change in capacitance with a little error of 0.13%. Thus, these results imply that the proposed algorithm is able to estimate the change in DC-link capacitance effectively. Accordingly, some embodiments of the present inventive concept provide an effective online monitoring of a capacitance value to detect a degradation of the DC-link capacitor, which is reflective of the health of the system.

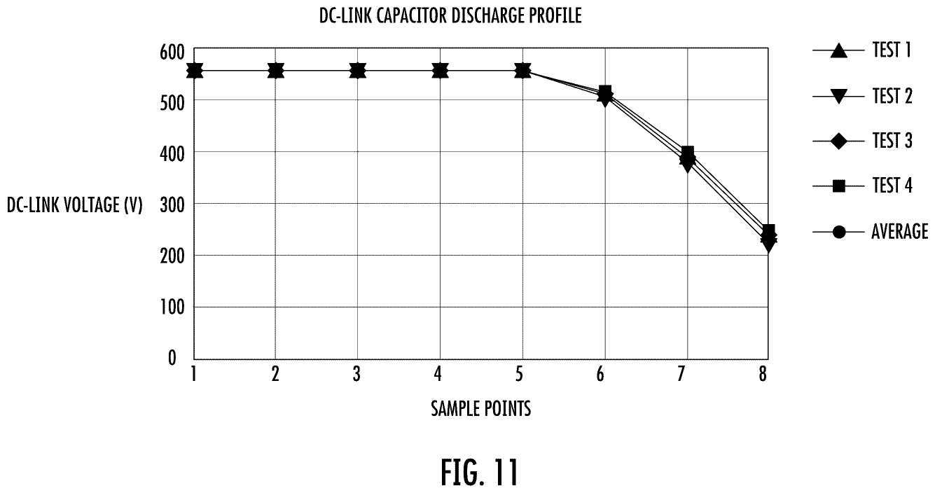

In particular, the capacitance value indicates the rate of discharge of the capacitor that can be identified by voltage measurement. In VFD, the discharge profile of the DC-link capacitor can be measured during the device power cycle. FIG. 11 is a graph illustrating a DC-link voltage profile for multiple instances when the power supply to the device was turned off with fixed sampling time. The average voltage at each sampling instance is computed to obtain the mean discharge profile of the DC-link capacitor to reduce, or possibly, minimize the sensing inaccuracies. The mean discharging profiles of the healthy and degraded capacitor are used to estimate the change in capacitance using Eqn. (7). If the change in capacitance goes above the threshold value, a warning to replace the capacitor is issued. As discussed above, the warning can be an audible alert, a text communication or the like without departing from the scope of the present inventive concept.

As discussed briefly above, some embodiments of the present inventive concept estimate the capacitance value using DC-link voltage, which is currently available with the drives in the current system. Thus, this solution may not require any additional sensors or hardware components to function. This saves time and cost.

The online approach discussed herein can monitor the health of the capacitor during running conditions of the converter system. This is contrary to many conventional approaches that are offline and generally require shutting down the system and interruptions in operation of the drive for capacitance estimation. These conventional solutions become challenging when the converter or drive is being utilized for critical applications.

The health monitoring solution in accordance with some embodiments of the present inventive concept is robust and accurate as the degradation in the capacitors are estimated based on combined results of two methods: an online DC-link voltage measurement based and a capacitor discharge profile. Methods in accordance with embodiments discussed herein are applicable for both single-phase and three-phase rectifier-based systems. Furthermore, the methods and systems discussed herein can be used for online health monitoring of electrolytic and film-type capacitors.

In the drawings and specification, there have been disclosed example embodiments of the inventive subject matter. Although specific terms are employed, they are used in a generic and descriptive sense only and not for purposes of limitation, the scope of the inventive subject matter being defined by the following claims

What is claimed is:

1. A method for monitoring health of a DC-link capacitor in a power converter, the method comprising:
measuring a DC-link voltage, wherein the DC-link voltage is a direct current voltage between a rectifier and an inverter;
filtering high-frequency noise from the measured DC-link voltage;
obtaining a peak value of the DC-link voltage and a minimum value of a DC-link voltage from the filtered DC-link voltage;
calculating a drive output power from the measured DC-link voltage and current signals;
calculating a charging time duration for the DC-link capacitor using a magnitude of the obtained peak value of the DC-link voltage and a magnitude of the minimum value of the DC-link voltage;
calculating a DC-link capacitance using the peak and minimum voltage magnitudes, calculated charging time duration, calculated drive output power, and frequency;
comparing the calculated DC-link capacitance with a baseline DC-link capacitance to determine a reduction in capacitance; and
determining the health of the DC-link capacitor based on the calculated reduction in capacitance.

2. The method of claim 1, wherein when a percentage reduction in capacitance exceeds a threshold value, a warning signal is issued indicating that the DC-link capacitor needs to be replaced.

3. The method of claim 1, wherein when a percentage reduction in capacitance does not exceed a threshold value, repeating the method until the threshold value is exceeded.

4. The method of claim 1, wherein filtering high frequency noise comprises filtering high frequency noise using a low-pass filter.

5. The method of claim 4, wherein the high frequency noise comprises noise greater than 1 kHz.

6. The method of claim 1, wherein charging time duration (a) is calculated using the following equation:
$$α = {cos}^{- 1} ( {V}_{dc 2} / {V}_{dc 1} )$$
wherein V_{dc1} is the peak value and V_{dc2} is the minimum value.

7. The method of claim 6, wherein calculating the DC-link capacitance comprises calculating the DC-link capacitance for a single-phase system using the following equation:
$${C}_{dc} = ( ( π - α ) / π ) ( ( {P}_{0} ) / ( {f}_{s} ( {V}_{dc 1} + {V}_{dc 2} ) ( {V}_{dc 1} - {V}_{dc 2} ) ) )$$
wherein C_{dc} is the DC-link capacitance; α is the charging time duration; Pₒ is load power; V_{dc1} is the peak value and V_{dc2} is the minimum value.

8. The method of claim 1, further comprising:
repeatedly calculating the DC-link capacitance using the peak and minimum voltage magnitudes, calculated charging time duration, calculated drive output power, and frequency; and
averaging the calculated DC-link capacitances.

9. The method of claim 1, wherein comparing the calculated DC-link capacitance with the measured DC-link capacitance to determine a reduction in capacitance comprises determining the reduction using a voltage profile during discharging.

10. A health monitoring system for monitoring the health of DC-link capacitors, the system comprising a controller that hosts a health monitoring algorithm that computes a capacitance of the DC-link capacitor and estimates the health of the capacitor, wherein the controller:
measures a DC-link voltage, wherein the DC-link voltage is a direct current voltage between a rectifier and an inverter;
filters high-frequency noise from the measured DC-link voltage;
obtains a peak value of the DC-link voltage and a minimum value of a DC-link voltage from the filtered DC-link voltage;
calculates a drive output power from the measured DC-link voltage and current signals;
calculates a charging time duration for the DC-link capacitor using a magnitude of the obtained peak value of the DC-link voltage and a magnitude of the minimum value of the DC-link voltage;
calculates a DC-link capacitance using the peak and minimum voltage magnitudes, calculated charging time duration, calculated drive output power, and frequency;
compares the calculated DC-link capacitance with a baseline DC-link capacitance to determine a reduction in capacitance; and
determines the health of the DC-link capacitor based on the calculated reduction in capacitance.

11. The system of claim 10, wherein when a percentage reduction in capacitance exceeds a threshold value, the controller issues a warning signal indicating that the DC-link capacitor needs to be replaced.

12. The system of claim 10, wherein when a percentage reduction in capacitance does not exceed a threshold value, the controller repeats the method until the threshold value is exceeded.

13. The system of claim 10, further comprises a low-pass filter and wherein the controller causes the low-pass filter to filter high frequency noise.

14. The system of claim 13, wherein the high frequency noise comprises noise greater than 1 kHz.

15. The system of claim 10, wherein the controller calculates charging time duration (α) using the following equation:
$$α = {cos}^{- 1} ( {V}_{dc 2} / {V}_{dc 1} )$$
wherein V_{dc1} is the peak value and V_{dc2} is the minimum value.

16. The system of claim 15, wherein the controller calculates the DC-link capacitance for a single-phase system using the following equation:
$${C}_{dc} = ( ( π - α ) / π ) ( ( {P}_{0} ) / ( {f}_{s} ( {V}_{dc 1} + {V}_{dc 2} ) ( {V}_{dc 1} - {V}_{dc 2} ) ) )$$
wherein C_{dc} is the DC-link capacitance; a is the charging time duration; Pₒ is the load power; V_{dc1} is the peak value and V_{dc2} is the minimum value.

17. The system of claim 10, wherein the controller further repeatedly calculates the DC-link capacitance using the peak and minimum voltage magnitudes, calculated charging time duration, calculated drive output power, and frequency and averages the calculated DC-link capacitances.

18. The system of claim 10, wherein the controller compares the calculated DC-link capacitance with the measured DC-link capacitance to determine a reduction in capacitance using a voltage profile during discharging.

19. The system of claim 10, wherein the health monitoring system monitors the health of the capacitor during running conditions.

20. The system of claim 10, wherein the system comprises:
a grid;
a VFD coupled to the grid;
the controller;
a display; and
an induction motor (IM), wherein the grid-connected VFD drives the induction motor in which the power converters are connected through an intermediate DC-link capacitor.
